(19) United States
(12) Patent Application Publication
(10) Pub. No.: US 2024/0372020 A1
(43) Pub. Date: Nov. 7, 2024

(54) PHOTOELECTRIC DETECTOR CHIP AND PREPARATION METHOD AND APPLICATION THEREOF

(71) Applicant: SOUTH CHINA UNIVERSITY OF TECHNOLOGY, Guangzhou (CN)

(72) Inventors: Guoqiang LI, Guangzhou (CN); Jixing CHAI, Guangzhou (CN); Wenliang WANG, Guangzhou (CN); Liang CHEN, Guangzhou (CN)

(73) Assignee: SOUTH CHINA UNIVERSITY OF TECHNOLOGY, Guangzhou (CN)

(21) Appl. No.: 18/030,513

(22) PCT Filed: Jan. 25, 2022
(86) PCT No.: PCT/CN2022/073672

§ 371 Date: Apr. 6, 2023

(30) Foreign Application Priority Data
Dec. 14, 2021 (CN) 202111523820.5

(51) Int. Cl. H01L 31/0304; H01L 31/101; H01L 31/11; H01L 31/18

(52) U.S. Cl. CPC H01L 31/03048; H01L 31/1856; H01L 31/1013; H01L 31/11

(57) ABSTRACT

A photoelectric detector chip and a preparation method and application thereof are provided. The photoelectric detector chip includes a bottom electrode, a first GaN layer, an i-In_{y}Ga_{1-y}N functional layer, a second GaN layer, an i-InₓGa₁₋ₓN functional layer, a third GaN layer, and a top electrode that are stacked sequentially, where 0≤x≤1, and y>x; the first GaN layer, the second GaN layer, and the third GaN layer are an n-GaN layer, a p-GaN layer, and an n-GaN layer respectively. The photoelectric detector chip is a vertical-structure dual-band chip. Compared with a transverse structure, the vertical structure can reduce carrier transition time, increase the response speed of the detector, and effectively improve the −3 dB bandwidth of the detector. The dual bands allow the photoelectric detector chip to load voltages in different directions, thus achieving photoelectric detection in different bands.

### CROSS REFERENCE TO THE RELATED APPLICATIONS

This application is the national phase entry of International Application No. PCT/CN2022/073672, filed on Jan. 25, 2022, which is based upon and claims priority to Chinese Patent Application No. 202111523820.5, filed on Dec. 14, 2021, the entire contents of which are incorporated herein by reference.

### TECHNICAL FIELD

The present disclosure relates to the technical field of photoelectric detectors, particularly to a photoelectric detector chip and a preparation method and application thereof.

### BACKGROUND

In recent years, with the popularization of semiconductor lighting technology, light-emitting diode (LED)-based visible light communication (VLC) has attracted widespread attention and gradually become a research hotspot. Modern communication scenarios require extremely high capacity and rate for communication, and multicolor LED-based VLC systems are proposed to solve the above problems. However, this also puts demands on photoelectric detectors, especially on the monolithic integration of multi-band response detectors.

The IIIA-VA compound semiconductor InₓGa₁₋ₓN material with a tunable bandgap (0.7 to 3.4 eV) applies to the operating wavelength of the light source to receive light signals to a maximum extent and effectively reduce noise and system costs, thus becoming the most promising candidate for the VLC photoelectric detector. However, the current research on InGaN-based photoelectric detectors is mainly focused on single-wavelength PIN-type and metal-semiconductor-metal (MSM)-type detectors with transverse structures. Due to the long response time of the transverse-structure detectors, the existing InGaN-based photoelectric detector can neither achieve multi-band detection nor meet the requirement of high-speed response.

### SUMMARY

The first technical problem to be solved by the present disclosure involves
providing a photoelectric detector chip. The photoelectric detector chip is a vertical-structure dual-band chip, where the dual bands allow the photoelectric detector chip to load voltages in different directions, thus achieving photoelectric detection in different bands.

The second technical problem to be solved by the present disclosure involves
providing a preparation method of the photoelectric detector chip.

The third technical problem to be solved by the present disclosure involves

Providing an application of the photoelectric detector chip.

To solve the first technical problem, the technical solution adopted by the present disclosure is as follows:

A photoelectric detector chip, including a bottom electrode, a first GaN layer, an i-In_{y}Ga_{1-y}N functional layer, a second GaN layer, an i-InₓGa₁₋ₓN functional layer, a third GaN layer, and a top electrode that are stacked sequentially,
where 0≤x<1 and 0≤y≤1.

When the first GaN layer is an n-GaN layer, the second GaN layer is a p-GaN layer and the third GaN layer is an n-GaN layer.

When the first GaN layer is a p-GaN layer, the second GaN layer is an n-GaN layer and the third GaN layer is a p-GaN layer.

The layers of the photoelectric detector chip are structure layers with the same or similar lattice constants, which avoids lattice mismatch and improves carrier mobility and lifetime to a certain extent, thereby improving the working performance of the device.

The photoelectric detector chip may be an n-i-p-i-n structure sharing a p-type material or a p-i-n-i-p structure sharing an n-type material based on two p-i-n structures as required.

Since the substrate is removed, the structure of the p-i-n-p-i-n or n-i-p-i-n functional region can be transferred to other flexible substrates when necessary to prepare a flexible device. Alternatively, the structure of the p-i-n-p-i-n or n-i-p-i-n may be transferred to other devices, to implement hybrid integration, to extend application functions.

According to an implementation of the present disclosure, the i-InₓGa₁₋ₓN functional layer and the i-In_{y}Ga_{1-y}N functional layer each have a thickness of 30 to 200 nm.

According to an implementation of the present disclosure, y>x.

In the i-InₓGa₁₋ₓN functional layer and i-In_{y}Ga_{1-y}N functional layer, a higher In content corresponds to a lower bandgap and y>x. Therefore, the bandgap of the i-InₓGa₁₋ₓN functional layer is higher than that of the i-In_{y}Ga_{1-y}N functional layer.

During epitaxial growth, the i-In_{y}Ga_{1-y}N functional layer made of a low-bandgap material is disposed at an upper portion, and the i-InₓGa₁₋ₓN functional layer made of a high-bandgap material is disposed at a lower portion. During device preparation, the materials are flipped, such that the high-bandgap material is disposed at the upper portion, and the low-bandgap is disposed at the lower portion. The combination of the high-bandgap material having a short absorption cutoff wavelength and the low-bandgap material having a long absorption cutoff wavelength maximizes the use of different bands.

According to an implementation of the present disclosure, the i-InₓGa₁₋ₓN functional layer is selected from an InₓGa₁₋ₓN film, an InₓGa₁₋ₓN/GaN film, or an InₓGa₁₋ₓN/InGaN film, and the i-In_{y}Ga_{1-y}N functional layer is selected from an In_{y}Ga_{1-y}N film, an In_{y}Ga_{1-y}N/GaN film or an In_{y}Ga_{1-y}N/InGaN film. The foregoing functional layers are combined according to a target detection band.

Preferably, InₓGa₁₋ₓN/GaN film is an InₓGa₁₋ₓN/GaN quantum well; the InₓGa₁₋ₓN/InGaN film is an InₓGa₁₋ₓN/InGaN quantum well; the In_{y}Ga_{1-y}N/GaN film is an In_{y}Ga_{1-y}N/GaN quantum well; the In_{y}Ga_{1-y}N/InGaN film is an In_{y}Ga_{1-y}N/InGaN quantum well.

The photoelectric detector chip loads voltages in different directions, thus achieving photoelectric detection in different bands.

Specifically, under a forward bias voltage of 1.5 V, an operating region of the photoelectric detector chip is the second GaN layer, the i-InₓGa₁₋ₓN functional layer, and the third GaN layer, and the −3 dB bandwidth of the chip is 170 MHz. Under a reverse bias voltage of −1.3 V, the operating region of the chip is the first GaN layer, the i-In_{y}Ga_{1-y}N functional layer, and the second GaN layer, and the −3 dB bandwidth of the chip is 220 MHz.

To solve the second technical problem, the technical solution adopted by the present disclosure is as follows:

A preparation method of the photoelectric detector chip includes the following steps:
sequentially growing a buffer layer, an intrinsic GaN layer, a third GaN layer, an i-InₓGa₁₋ₓN functional layer, a second GaN layer, an i-In_{y}Ga_{1-y}N functional layer, and a first GaN layer on a substrate;
providing a bottom electrode on a surface of the first GaN layer;
removing the substrate, the buffer layer, and the intrinsic GaN layer; and
providing a top electrode on a surface of the third GaN layer to obtain the photoelectric detector chip.

Through one epitaxy process, response layer structures for multiple bands are grown on the substrate, and a vertical-structure dual-band InGaN-based photoelectric detector is prepared at the same time. Compared with a transverse structure, the vertical structure can reduce carrier transition time, increase the response speed of the detector, and effectively improve the −3 dB bandwidth of the detector. The vertical-structure dual-band InGaN-based photoelectric detector can meet the demand of a dual-color LED-based VLC system for high-bandwidth multiband-response photoelectric detector chips.

According to an implementation of the present disclosure, a method for the sequential growth on the substrate includes at least one of metal-organic chemical vapor deposition (MOCVD), pulsed laser deposition (PLD), and molecular beam epitaxy (MBE).

According to an implementation of the present disclosure, the substrate is at least one of a silicon substrate, a sapphire substrate, or a silicon carbide substrate, and has a thickness of 300 to 450 μm.

According to an implementation of the present disclosure, the buffer layer includes an AlN buffer layer and an AlGaN buffer layer.

According to an implementation of the present disclosure, the grown AlN buffer layer has a thickness of 50 to 150 nm, and the grown AlGaN buffer layer has a thickness of 250 to 400 nm.

According to an implementation of the present disclosure, the intrinsic GaN layer has a thickness of 1 to 3 μm, the third GaN layer has a thickness of 1 to 3 μm, the i-InₓGa₁₋ₓN functional layer has a thickness of 80 to 150 nm, the second GaN layer has a thickness of 100 to 150 nm, the i-In_{y}Ga_{1-y}N functional layer has a thickness of 80 to 150 nm, and the first GaN layer has a thickness of 300 to 500 nm.

According to an implementation of the present disclosure, a method for removing the substrate, the buffer layer, and the intrinsic GaN layer includes at least one of wet etching, laser lift-off, or mechanical exfoliation.

According to an implementation of the present disclosure, the bottom electrode is composed of Ti/Al/Ni/Au in sequence;
the top electrode is composed of Ti/Al/Ni/Au in sequence;
the bottom electrode and the top electrode each have a thickness of 0.1 to 10 μm, preferably, a thickness of 215 to 360 nm.

The bottom electrode needs to provide certain support, and therefore, is required to be thicker.

Deposition of the Ti/Al/Ni/Au electrode on the photoelectric detector chip can form an ohmic contact mechanism. As a cover layer of Ti/Al, Ni/Au can prevent mutual diffusion of Ti, Al, and Au and acts as an antioxidant for the contact layer.

According to an implementation of the present disclosure, the bottom electrode is prepared by using an electron beam evaporation system.

According to an implementation of the present disclosure, the third GaN layer is spin-coated with a photoresist and subject to exposure and development, and then a top electrode is prepared by using the electron beam evaporation system.

According to an implementation of the present disclosure, the bottom electrode and the top electrode are annealed at an annealing temperature of 800 to 850° C. for 30 to 50 s.

According to further another aspect of the present disclosure, an application of the photoelectric detector chip in VLC is provided.

The photoelectric detector chip can implement dual-band detection. Compared with dual-band detection implemented by a combination of different photoelectric detectors, the photoelectric detector chip is more efficient.

One of the technical solutions at least achieves one of the following advantages:

1. During epitaxial growth, the i-In_{y}Ga_{1-y}N functional layer made of a low-bandgap material is disposed at an upper portion, and the i-InₓGa₁₋ₓN functional layer made of a high-bandgap material is disposed at a lower portion. During device preparation, the materials are flipped, such that the high-bandgap material is disposed at the upper portion, and the low-bandgap is disposed at the lower portion. The combination of the high-bandgap material having a short absorption cutoff wavelength and the low-bandgap material having a long absorption cutoff wavelength maximizes the use of different bands.

2. Through one epitaxy process, response layer structures for multiple bands are grown on the substrate, and a vertical-structure dual-band InGaN-based photoelectric detector is prepared at the same time. Compared with a transverse structure, the vertical structure can reduce carrier transition time, increase the response speed of the detector, and effectively improve the −3 dB bandwidth of the detector. The dual bands allow the photoelectric detector chip to load voltages in different directions, thus achieving photoelectric detection in different bands.

### BRIEF DESCRIPTION OF THE DRAWINGS

The accompanying drawings which constitute a part of the description of the present disclosure are intended to provide a further understanding of the present disclosure. The exemplary examples of the present disclosure and descriptions thereof are intended to explain the present disclosure and do not constitute as a limitation to the present disclosure.

FIG. 1 is a schematic structural diagram of an epitaxial growth process of a photoelectric detector chip according to Embodiment 1.

FIG. 2 is a sectional view of a device structure of the photoelectric detector chip according to Embodiment 1.

FIG. 3 is a sectional view of a device structure of a photoelectric detector chip according to Embodiment 2.

FIG. 4 is a sectional view of a device structure of a photoelectric detector chip according to Embodiment 3.

FIG. 5 is a sectional view of a device structure of a photoelectric detector chip according to Embodiment 4.

FIG. 6 shows response curves in dual bands of the photoelectric detector chip according to Embodiment 1.

FIG. 7 shows bandwidth curves in dual bands of the photoelectric detector chip according to Embodiment 1.

### DETAILED DESCRIPTION OF THE EMBODIMENTS

The embodiments of the present disclosure are described below in detail. Examples of the embodiments are shown in the drawings. The same or similar numerals represent the same or similar elements or elements having the same or similar functions throughout the specification.

The embodiments described below with reference to the drawings are exemplary. They are only used to explain the present disclosure and should not be construed as a limitation of the present disclosure.

The “first”, “second”, “third” and the like used in the description of the present disclosure are merely intended to distinguish technical features, rather than to indicate or imply relative importance or implicitly indicate a number of the indicated technical features or implicitly indicate a sequence relationship of the indicated technical features.

It should be understood that, in the description of the present disclosure, the orientation or position relationships indicated by terms such as “upper”, “lower”, “front”, “rear”, “left”, and “right” are shown in the drawings. These terms are merely intended to facilitate and simplify the description of the present disclosure, rather than to indicate or imply that the mentioned apparatus or components must have a specific orientation or must be constructed and operated in a specific orientation. Therefore, these terms should not be understood as a limitation of the present disclosure.

In the description of the present disclosure, unless otherwise explicitly defined, the words such as “arrange”, “install” and “connect” should be understood in a broad sense, and those skilled in the technical field can reasonably determine the specific meanings of the above words in the present disclosure in combination with the specific contents of the technical solutions.

### Embodiment 1

In Embodiment 1, in an i-In_{y}Ga_{1-y}N functional layer, y=0.4, and the bandgap is 1.97 eV.

In an i-InₓGa₁₋ₓN functional layer, x=0.15, and the bandgap is 2.81 eV.

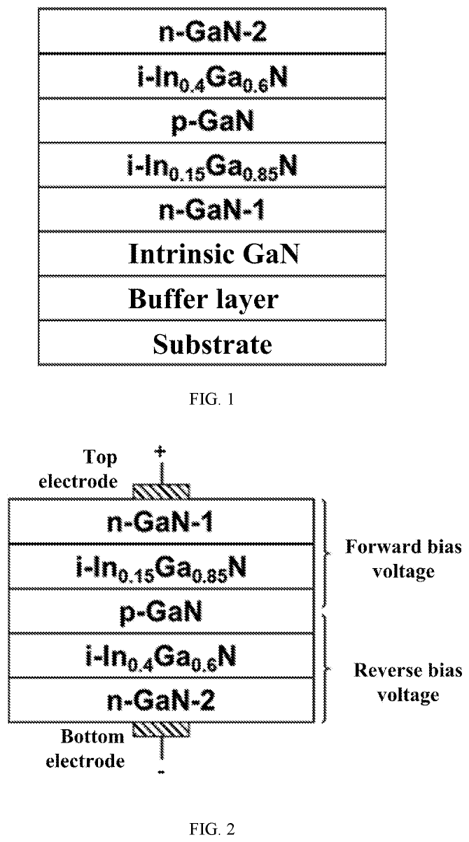

This embodiment provides a photoelectric detector chip. As shown in FIG. 1, in an epitaxial growth process, the structure of the photoelectric detector chip includes a substrate, a buffer layer, an intrinsic GaN layer, an n-GaN-1 layer, an i-In_{0.15}Ga_{0.75}N functional layer, a p-GaN layer, an i-In_{0.4}Ga_{0.6}N functional layer, and an n-GaN-2 layer in sequence from bottom to top. A specific growth process is as follows:

On the substrate with a thickness of 300 μm, an MOCVD method is adopted for growth with raw materials of trimethyl gallium (Ga(CH₃)₃, TMGa), trimethyl indium (In(CH₃)₃, TMIn), and trimethyl aluminum (Al(CH₃)₃, TMAl). AlN with a thickness of 50 nm, an AlGaN layer with a thickness of 250 nm, a GaN layer with a thickness of 1 μm, an n-GaN-1 layer with a thickness of 1 μm, an i-In_{0.15}Ga_{0.85}N functional layer with a thickness of 80 nm, a p-GaN layer with a thickness of 100 nm, an i-In_{0.4}Ga_{0.6}N functional layer with a thickness of 80 nm, and n-GaN-2 with a thickness of 300 nm are grown sequentially.

The device structure of the photoelectric detector chip is as shown in FIG. 2, which includes a bottom electrode, an n-GaN-2 layer, an i-In_{0.4}Ga_{0.6}N functional layer, a p-GaN layer, an i-In_{0.15}Ga_{0.75}N functional layer, an n-GaN-1 layer, and a top electrode in sequence from bottom to top. A specific preparation process is as follows:

(1) The bottom n-electrode is prepared on a surface of the n-GaN-2 layer by using an electron beam evaporation system, where the electrode is made of Ti, Al, Ni, and Au with thicknesses of 5 nm, 90 nm, 60 nm, and 60 nm, respectively.

(2) The substrate, the buffer layer, and the intrinsic GaN layer are removed from the epitaxial materials of the photoelectric detector chip using wet etching.

(3) The surface of the n-GaN-1 layer is spin-coated with a photoresist and subject to exposure and development again, and then the top electrode is prepared by using the electron beam evaporation system. The top electrode is made of Ti, Al, Ni, and Au in sequence with thicknesses of 5 nm, 90 nm, 60 nm, and 60 nm, respectively. The prepared electrode is annealed by using a rapid annealing furnace at an annealing temperature of 800° C. for 30 s to obtain the photoelectric detector chip.

### Embodiment 2

In Embodiment 2, in an i-In_{y}Ga_{1-y}N functional layer, y=0.15, and the bandgap is 2.81 eV.

In an i-InₓGa₁₋ₓN functional layer, x=0, and the bandgap is 3.4 eV.

This embodiment provides a photoelectric detector chip. In an epitaxial growth process, the structure of the photoelectric detector chip includes a substrate, a buffer layer, an intrinsic GaN layer, an n-GaN-1 layer, an i-GaN functional layer, a p-GaN layer, an i-In_{0.15}Ga_{0.75}N functional layer, and an n-GaN-2 layer in sequence from bottom to top. A growth process is as follows:

(1) On the substrate with a thickness of 400 μm, an MBE method is adopted for growth with raw materials of high-purity indium (In, 99.99999%), high-purity gallium (Ga, 99.99999%), and high-purity aluminum (Al, 99.99999%). AlN with a thickness of 100 nm, an AlGaN layer with a thickness of 300 nm, a GaN layer with a thickness of 2 μm, an n-GaN-1 layer with a thickness of 2 μm, an i-GaN functional layer with a thickness of 100 nm, a p-GaN layer with a thickness of 130 nm, an i-In_{0.15}Ga_{0.75}N functional layer with a thickness of 400 nm, and n-GaN-2 with a thickness of 300 nm are grown sequentially.

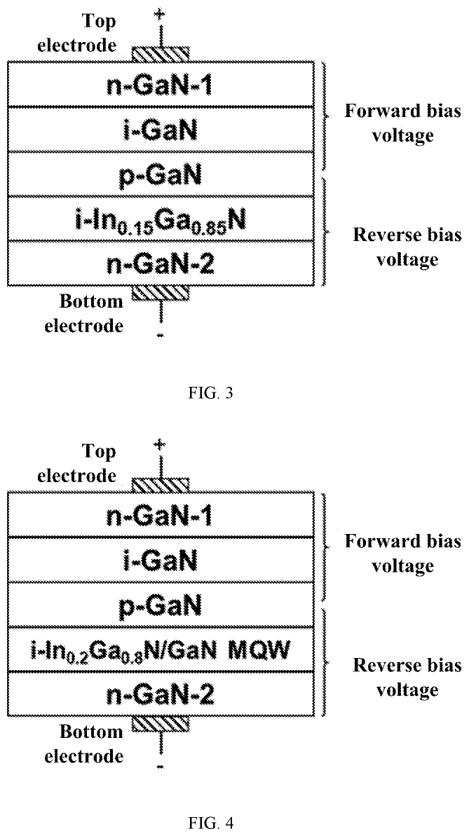

The device structure of the photoelectric detector chip is as shown in FIG. 3, which includes a bottom electrode, an n-GaN-2 layer, an i-In_{0.15}Ga_{0.75}N functional layer, a p-GaN layer, an i-GaN functional layer, an n-GaN-1 layer, and a top electrode in sequence from bottom to top. A specific preparation process is as follows:

(1) The bottom electrode is prepared on a surface of the n-GaN-2 layer by using an electron beam evaporation system, where the electrode is made of Ti, Al, Ni, and Au with thicknesses of 5 nm, 120 nm, 80 nm, and 80 nm, respectively.

(2) The substrate, the buffer layer, and the intrinsic GaN layer are removed from the epitaxial materials of the photoelectric detector chip using mechanical exfoliation.

(3) The surface of the n-GaN-1 layer is spin-coated with a photoresist and subject to exposure and development again, and then the top electrode is prepared by using the electron beam evaporation system. The top electrode is made of Ti, Al, Ni, and Au in sequence with thicknesses of 5 nm, 120 nm, 80 nm, and 80 nm, respectively. The prepared electrode is annealed by using a rapid annealing furnace at an annealing temperature of 800° C. for 30 s to obtain the photoelectric detector chip.

### Embodiment 3

In Embodiment 3, in an i-In_{y}Ga_{1-y}N functional layer, y=0.2, and the bandgap is 2.63 eV.

In an i-InₓGa₁₋ₓN functional layer, x=0, and the bandgap is 3.4 eV.

This embodiment provides a photoelectric detector chip. In an epitaxial growth process, the structure of the photoelectric detector chip includes a substrate, a buffer layer, an intrinsic GaN layer, an n-GaN-1 layer, an i-GaN functional layer, a p-GaN layer, an i-In_{0.2}Ga_{0.8}N/GaN quantum well functional layer, and an n-GaN-2 layer in sequence from bottom to top. A growth process is as follows:

(1) On the substrate with a thickness of 450 μm, a PLD method is adopted for growth with raw materials of high-purity indium (In, 99.99999%), high-purity gallium (Ga, 99.99999%), and high-purity aluminum (Al, 99.99999%). AlN with a thickness of 150 nm, an AlGaN layer with a thickness of 400 nm, a GaN layer with a thickness of 3 μm, an n-GaN-1 layer with a thickness of 3 μm, an i-GaN functional layer with a thickness of 150 nm, a p-GaN layer with a thickness of 150 nm, an i-In_{0.2}Ga_{0.8}N/GaN quantum well functional layer with a thickness of 150 nm, and n-GaN-2 with a thickness of 500 nm are grown sequentially.

The device structure of the photoelectric detector chip is shown in FIG. 4, which includes a bottom n-electrode, an n-GaN-2 layer, an i-In_{0.2}Ga_{0.8}N/GaN quantum well functional layer, a p-GaN layer, a p-electrode, an i-GaN functional layer, an n-GaN-1 layer, and a top n-electrode in sequence from bottom to top. A specific preparation process is as follows:

(1) A bottom n-electrode is prepared on a surface of the n-GaN-2 layer by using an electron beam evaporation system, where the electrode is made of Ti, Al, Ni, and Au with thicknesses of 10 nm, 150 nm, 100 nm, and 100 nm, respectively.

(2) The substrate, the buffer layer, and the intrinsic GaN layer are removed from the epitaxial materials of the photoelectric detector chip using wet etching and mechanical exfoliation.

(3) The surface of the n-GaN-1 layer is spin-coated with a photoresist and subject to exposure and development again, and then the top electrode is prepared by using the electron beam evaporation system. The top electrode is made of Ti, Al, Ni, and Au in sequence with thicknesses of 10 nm, 150 nm, 100 nm, and 100 nm, respectively. The prepared electrode is annealed by using a rapid annealing furnace at an annealing temperature of 800° C. for 30 s to obtain the photoelectric detector chip.

### Embodiment 4

In Embodiment 4, in an i-In_{y}Ga_{1-y}N functional layer, y=0.4, and the bandgap is 1.97 eV.

In an i-InₓGa₁₋ₓN functional layer, x=0.15, and the bandgap is 2.81 eV.

This embodiment provides a photoelectric detector chip. In an epitaxial growth process, the structure of the photoelectric detector chip includes a substrate, a buffer layer, an intrinsic GaN layer, a p-GaN-1 layer, an i-In_{0.15}Ga_{0.75}N functional layer, an n-GaN layer, an i-In_{0.4}Ga_{0.6}N functional layer, and a p-GaN-2 layer in sequence from bottom to top. A growth process is as follows:

On the substrate with a thickness of 300 μm, an MOCVD method is adopted for growth with raw materials of trimethyl gallium (Ga(CH₃)₃, TMGa), trimethyl indium (In(CH₃)₃, TMIn), and trimethyl aluminum (Al(CH₃)₃, TMAl). AlN with a thickness of 50 nm, an AlGaN layer with a thickness of 250 nm, a GaN layer with a thickness of 1 μm, a p-GaN-1 layer with a thickness of 1 μm, an i-In_{0.15}Ga_{0.85}N functional layer with a thickness of 80 nm, an n-GaN layer with a thickness of 100 nm, an i-In_{0.4}Ga_{0.6}N functional layer with a thickness of 80 nm, and n-GaN-2 with a thickness of 300 nm are grown sequentially.

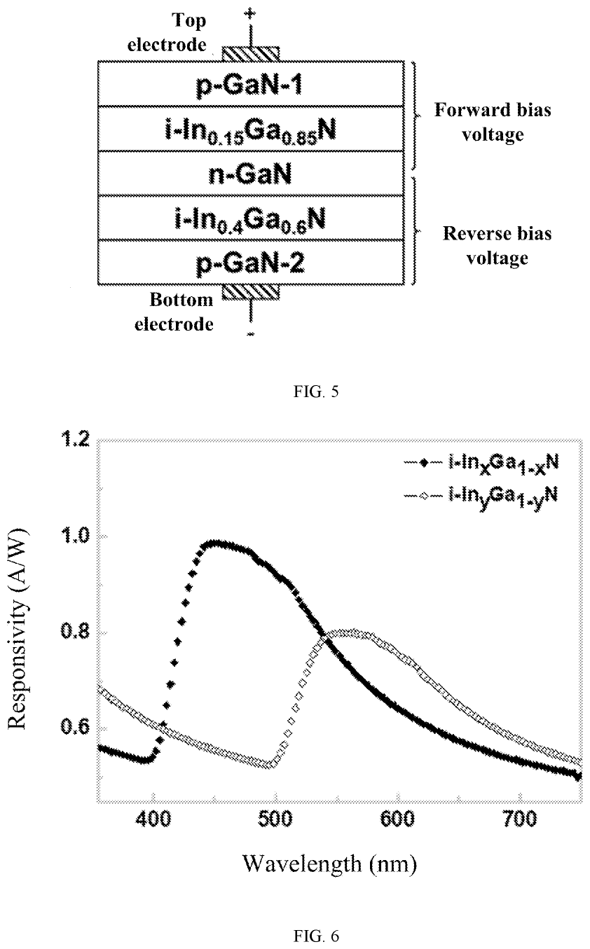

The device structure of the photoelectric detector chip is as shown in FIG. 5, which includes a bottom electrode, a p-GaN-2 layer, an i-In_{0.4}Ga_{0.6}N functional layer, an n-GaN layer, an i-In_{0.15}Ga_{0.75}N functional layer, a p-GaN-1 layer, and a top electrode in sequence from bottom to top. A specific preparation process is as follows:

(1) The bottom p-electrode is prepared on a surface of the p-GaN-2 layer by using an electron beam evaporation system, where the electrode is made of Ti, Al, Ni, and Au with thicknesses of 5 nm, 90 nm, 60 nm, and 60 nm, respectively.

(2) The substrate, the buffer layer, and the intrinsic GaN layer are removed from the epitaxial materials of the photoelectric detector chip using wet etching.

(3) The surface of the p-GaN-1 layer is spin-coated with a photoresist and subject to exposure and development, and then the top electrode is prepared by using the electron beam evaporation system. The top electrode is made of Ti, Al, Ni, and Au in sequence with thicknesses of 5 nm, 90 nm, 60 nm, and 60 nm, respectively. The prepared electrode is annealed by using a rapid annealing furnace at an annealing temperature of 800° C. for 30 s to obtain the photoelectric detector chip.

### Performance Test:

FIG. 6 shows response curves in dual bands of the photoelectric detector chip according to Embodiment 1. Under a forward bias voltage of 1.5 V, an operating region of the device is the second GaN layer, the i-InₓGa₁₋ₓN functional layer, and the third GaN layer, and the responsivity of the device is 0.98 A/W. Under a reverse bias voltage of −1.3 V, the operating region of the device is the first GaN layer, the i-In_{y}Ga_{1-y}N functional layer, and the second GaN layer, and the responsivity of the device is 0.81 A/W.

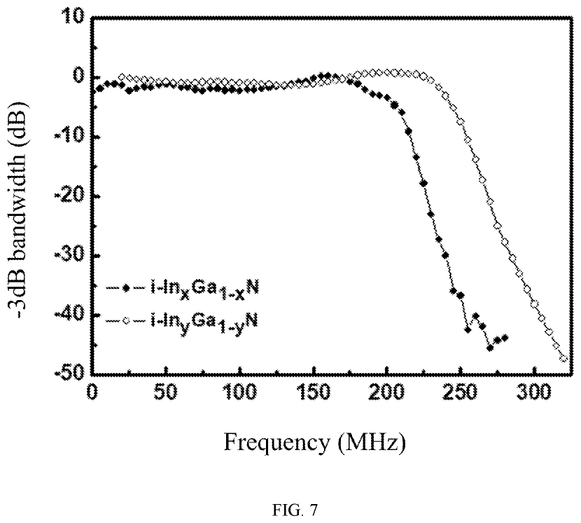

FIG. 7 shows bandwidth curves in dual bands of the photoelectric detector chip according to Embodiment 1. Under a forward bias voltage of 1.5 V, the operating region of the device is the second GaN layer, the i-InₓGa₁₋ₓN functional layer, and the third GaN layer, and the −3 dB bandwidth of the device is 170 MHz. Under a reverse bias voltage of −1.3 V, the operating region of the device is the first GaN layer, the i-In_{y}Ga_{1-y}N functional layer, and the second GaN layer, and the −3 dB bandwidth of the device is 220 MHz.

The foregoing are merely embodiments of the present disclosure and do not constitute a limitation on the scope of the present disclosure. Any equivalent change made by using the description and the accompanying drawings of the present disclosure, or the direct or indirect application thereof in related technical fields, shall still fall in the protection scope of the present disclosure.

What is claimed is:

1. A photoelectric detector chip, comprising:
a bottom electrode, a first GaN layer, an i-In_{y}Ga_{1-y}N functional layer, a second GaN layer, an i-InₓGa₁₋ₓN functional layer, a third GaN layer, and a top electrode, wherein the bottom electrode, the first GaN layer, the i-In_{y}Ga_{1-y}N functional layer, the second GaN layer, the i-In_{y}Ga_{1-y}N functional layer, the third GaN layer, and the top electrode are stacked sequentially;
wherein 0≤x<1, and 0≤y≤1;
when the first GaN layer is an n-GaN layer, the second GaN layer is a p-GaN layer and the third GaN layer is an n-GaN layer; and
when the first GaN layer is a p-GaN layer, the second GaN layer is an n-GaN layer, and the third GaN layer is a p-GaN layer.

2. The photoelectric detector chip according to claim 1, wherein y>x.

3. The photoelectric detector chip according to claim 1, wherein the i-InₓGa₁₋ₓN functional layer and the i-In_{y}Ga_{1-y}N functional layer each have a thickness of 30 to 200 nm.

4. The photoelectric detector chip according to claim 3, wherein the i-InₓGa₁₋ₓN functional layer is one selected from the group consisting of an InₓGa₁₋ₓN film, an InₓGa₁₋ₓN/GaN film, and an InₓGa₁₋ₓN/InGaN film; and the i-In_{y}Ga_{1-y}N functional layer is one selected from the group consisting of an In_{y}Ga_{1-y}N film, an In_{y}Ga_{1-y}N/GaN film and an In_{y}Ga_{1-y}N/InGaN film.

5. A preparation method of the photoelectric detector chip according to claim 1, comprising the following steps:
sequentially growing a buffer layer, an intrinsic GaN layer, the third GaN layer, the i-InₓGa₁₋ₓN functional layer, the second GaN layer, the i-In_{y}Ga_{1-y}N functional layer, and the first GaN layer on a substrate;
providing the bottom electrode on a surface of the first GaN layer;
removing the substrate, the buffer layer, and the intrinsic GaN layer; and
providing the top electrode on a surface of the third GaN layer to obtain the photoelectric detector chip.

6. The preparation method according to claim 5, wherein a method for the sequential growth on the substrate comprises at least one selected from the group consisting of metal-organic chemical vapor deposition, pulsed laser deposition, and molecular beam epitaxy.

7. The preparation method according to claim 5, wherein
a method for removing the substrate, the buffer layer, and the intrinsic GaN layer comprises at least one selected from the group consisting of wet etching, laser lift-off, and mechanical exfoliation.

8. The preparation method according to claim 5, wherein
the bottom electrode and the top electrode are composed of same materials, comprising Ti/Al/Ni/Au in sequence; and
the bottom electrode and the top electrode each have a thickness of 0.1 to 10 μm.

9. The preparation method according to claim 8, wherein the bottom electrode and the top electrode are annealed at an annealing temperature of 800 to 850° C. for 30 to 50 s.

10. An application method of the photoelectric detector chip according to claim 1 in a visible light communication.

11. The preparation method according to claim 5, wherein in the photoelectric detector chip, y>x.

12. The preparation method according to claim 5, wherein in the photoelectric detector chip, the i-InₓGa₁₋ₓN functional layer and the i-In_{y}Ga_{1-y}N functional layer each have a thickness of 30 to 200 nm.

13. The preparation method according to claim 12, wherein in the photoelectric detector chip, the i-InₓGa₁₋ₓN functional layer is one selected from the group consisting of an InₓGa₁₋ₓN film, an InₓGa₁₋ₓN/GaN film, and an InₓGa₁₋ₓN/InGaN film; and the i-In_{y}Ga_{1-y}N functional layer is one selected from the group consisting of an In_{y}Ga_{1-y}N film, an In_{y}Ga_{1-y}N/GaN film and an In_{y}Ga_{1-y}N/InGaN film.

14. The application method according to claim 10, wherein in the photoelectric detector chip, y>x.

15. The application method according to claim 10, wherein in the photoelectric detector chip, the i-InₓGa₁₋ₓN functional layer and the i-In_{y}Ga_{1-y}N functional layer each have a thickness of 30 to 200 nm.

16. The application method according to claim 15, wherein in the photoelectric detector chip, the i-InₓGa₁₋ₓN functional layer is one selected from the group consisting of an InₓGa₁₋ₓN film, an InₓGa₁₋ₓN/GaN film, and an InₓGa₁₋ₓN/InGaN film; and the i-In_{y}Ga_{1-y}N functional layer is one selected from the group consisting of an In_{y}Ga_{1-y}N film, an In_{y}Ga_{1-y}N/GaN film and an In_{y}Ga_{1-y}N/InGaN film.
